(19) United States
(12) Patent Application Publication
(10) Pub. No.: US 2020/0219862 A1
(43) Pub. Date: Jul. 9, 2020

(54) DISPLAY APPARATUS AND METHOD OF MANUFACTURING DISPLAY APPARATUS THEREOF

(71) Applicant: SAMSUNG ELECTRONICS CO., LTD., Suwon-si (KR)

(72) Inventors: Seungryong HAN, Suwon-si (KR); Byungchul KIM, Suwon-si (KR); Dongyeob LEE, Suwon-si (KR)

(73) Assignee: SAMSUNG ELECTRONICS CO., LTD., Suwon-si (KR)

(21) Appl. No.: 16/736,057

(22) Filed: Jan. 7, 2020

(30) Foreign Application Priority Data
Jan. 7, 2019 (KR) 10-2019-0001769

(51) Int. Cl. H01L 25/16

(52) U.S. Cl. CPC H01L 25/162; H01L 25/167

(57) ABSTRACT

Provided is a method of manufacturing display apparatus including processing side surfaces of a plurality of display modules, each of the plurality of display modules including a plurality of micro light emitting diodes (LEDs) provided in pixels on an upper surface of each of the plurality of display modules, and providing the plurality of processed display modules such that the pixels of the plurality of processed display modules are provided at a same interval, respectively, wherein each of the plurality of display modules has a rectangular shape, and wherein the processing the side surfaces of the plurality of display modules includes processing a first side surface of each of the plurality of display modules and a second side surface of each of the plurality of display modules that are adjacent to the first side surface.

### CROSS-REFERENCE TO RELATED APPLICATIONS

This application is based on and claims priority under 35 U.S.C. § 119 to Korean Patent Application No. 10-2019-0001769, filed on Jan. 7, 2019 in the Korean Intellectual Property Office, the disclosure of which is incorporated herein by reference in its entirety.

### BACKGROUND

### 1. Field

The disclosure relates to a display apparatus with improved luminance uniformity and reduced manufacturing costs, and a manufacturing method thereof.

### 2. Description of the Related Art

A micro LED is formed of an ultra-small inorganic luminous material, and can emit light by itself to display an image. The micro LED refers to an ultra-small LED having a length of one tenth and an area of one hundredth compared to a general light emitting diode (LED) chip, and a width, length and height of 10 to 100 micrometers (μm).

A display screen of a display apparatus may be implemented by arranging a plurality of display modules having a plurality of micro LEDs arranged thereon, respectively. However, interval spaces between the plurality of display modules need to be minimized to realize uniform luminance of the display screen and to minimize seams between the plurality of display modules, and the plurality of display modules need to be arranged in order for spacing between the plurality of micro LEDs implementing the display screen to be same.

However, when the plurality of display modules are arranged based on physical matching, there has been a problem, due to manufacturing tolerances, that the space between the plurality of micro LEDs is not constant so that uniform luminance is not realized and a seam is recognized on the display screen.

### SUMMARY

Provided are a display device with improved luminance uniformity and reduced manufacturing costs, and a manufacturing method thereof.

Additional aspects will be set forth in part in the description which follows and, in part, will be apparent from the description, or may be learned by practice of the presented embodiments.

In accordance with an aspect of the disclosure, provided is a method of manufacturing display apparatus including processing side surfaces of a plurality of display modules, each of the plurality of display modules including a plurality of micro light emitting diodes (LEDs) provided in pixels on an upper surface of each of the plurality of display modules, and providing the plurality of processed display modules such that the pixels of the plurality of processed display modules are provided at a same interval, respectively, wherein each of the plurality of display modules has a rectangular shape, and wherein the processing the side surfaces of the plurality of display modules includes processing a first side surface of each of the plurality of display modules and a second side surface of each of the plurality of display modules that are adjacent to the first side surface.

The processing the side surfaces of the plurality of display modules may include processing at least two display modules of the plurarlity of display modules such that at least two or more display modules of the plurality of display modules have different surface areas.

The method may further include forming an adhesive layer on one surface of a transparent cover, wherein the providing the plurality of processed display modules includes providing the first processed display module and the sescond processed display module on the transparent cover, respectively, such that intervals between a plurality of first edge micro LEDs provided on one side surface of the first processed display module among the plurality of processed display module are equal to intervals between a plurality of second edge micro LEDs provided on one side surface of the second processed display module that are provided adjacent to one side surface of the first processed display module, and providing the plurality of processed display modules on a transparent cover formed with the adhesive layer.

The processing may further include processing a side surface of the first display module such that a distance between the plurality of first edge micro LEDs and one side surface of the first display module is smaller than a distance between each of the plurality of micro LEDs.

The processing the side surfaces of the plurality of display modules may further include processing the side surface of the first display module such that the processed side surface of the first display module is parallel to at least one of rows and columns of the plurality of first micro LEDs provided on the first display module.

The providing the plurality of processed display modules may further include providing the first processed display module and the sescond processed display module on the transparent cover such that the first processed display module and the second processed display module are provided with an interval space between the first processed display module and the second processed display module.

The transparent cover may include a covering formed in the form of a lattice and configured to absorb external light, and the providing the plurality of processed display modules may further include providing the first processed display module and the second processed display module on the transparent cover such that the interval space is covered by the covering.

The providing the plurality of processed display modules may further include providing the first processed display module and the second processed display module on the transparent cover such that rows and columns of the plurality of the first micro LEDs provided on the first processed display module are parallel to rows and columns of the plurality of second micro LEDs provided on the second processed display module, respectively.

The providing the plurality of processed display modules may further include providing the first processed display module and the second processed display module on the transparent cover such that the rows of the first processed display module and the rows of the second processed display module are collinear.

The providing the plurality of processed display modules may further include providing the first processed display module and the second processed display module on the transparent cover such that the columns of the first processed display module and the columns of the second processed display module are collinear.

The method may further include forming side wirings on two sides of the plurality of processed display modules, respectively, other than the first side surface and the second side surface of the plurality of processed display modules.

The method may further include compressing thermally the plurality of processed display modules, and filling the adhesive layer in the interval space.

In accordance with another aspect of the disclosure, provided is a display apparatus including a plurality of display modules in which a plurality of a micro light emitting diodes (LEDs) are provided in pixels, respectively, and a transparent cover provided to face the plurality of micro LEDs on an upper part of the plurality of display modules, wherein each of the plurality of display modules include a thin film transistor substrate electrically connected to the plurality of micro LEDs, each of the plurality of display modules including a glass substrate and a plurality of thin film transistors provided on an upper surface of the glass substrate, and a driving driver provided on a surface of the glass substrate and configured to drive the plurality of micro LEDs, and wherein at least two or more display modules of the plurality of display modules have different surface areas.

A shortest distance between a first edge micro LED provided on one side surface of a plurality of first micro LEDs provided on a first processed display module among the plurality of processed display modules and a side surface of the first processed display module adjacent to the first edge micro LED may be different, and wherein the first processed display module and the second processed display module provided adjacent to the first processed display module may be provided such that an interval between the first edge micro LED of the first processed display module and the second edge micro LED provided one side surface of a plurality of second micro LEDs of the second processed display module is regular.

The plurality of processed display modules have a rectangular shape, respectively, wherein the first processed display module may include a first side surface, a second side surface adjacent to the first side surface, a first processed surface facing the first side surface, and a second processed surface facing the second side surface and adjacent to the first processed surface, and wherein the first processed surface and the second processed surface are covered by a covering.

The first processed surface may be parallel to rows of the plurality of first micro LEDs.

The first processed surface may be parallel to columns of the plurality of first micro LEDs.

The plurality of micro LEDs may include a red micro LED configured to emit red light, a green micro LED configured to emit green light, and a blue micro LED configured to emit blue light, and wherein the red micro LED, the green micro LED and the blue micro LED are included in one pixel.

The display apparatus may further include an adhesive layer provided between the plurality of display modules and the transparent cover, and configured to fix the plurality of display modules on the transparent cover.

The transparent cover may further include an additional covering that covers space between the plurality of micro LEDs

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is an exploded perspective view illustrating a display apparatus according to an embodiment;

FIG. 2 is a top view illustrating a transparent cover according to an embodiment;

FIG. 3 is a top view illustrating a plurality of display modules according to an embodiment;

FIG. 4A is a top view illustrating a first and second processed display modules according an embodiment;

FIG. 4B is a cross section view taken along line A-A of FIG. 4;

FIG. 4C is a block diagram illustrating an operation of a display module according to an embodiment;

FIG. 5 is a top view illustrating a processing area of a first processed display module according to an embodiment;

FIG. 6 is a top view illustrating that a plurality of display modules are disposed on a transparent cover according to an embodiment;

FIG. 7 is a cross section view taken along line B-B of FIG. 6;

FIG. 8A is a top view illustrating a process of processing of a first display module according to an embodiment;

FIG. 8B is a top view illustrating a process of processing of a second display module according to an embodiment;

FIG. 9A is a top view illustrating a first processed display module according to a modified embodiment;

FIG. 9B is a cross section view taken along line F-F of FIG. 9A; and

FIGS. 10 to 14 are schematic diagrams illustrating a process of arranging a plurality of processed display modules.

### DETAILED DESCRIPTION OF EXEMPLARY EMBODIMENTS

Exemplary embodiments of the present disclosure will now be described in greater detail with reference to the accompanying drawings. However, the disclosure is not limited to embodiments disclosed below and may be implemented in various forms, and various changes may be made. However, descriptions of the embodiments are provided to make the disclosure complete, and to fully inform the scope of the disclosure to those skilled in the art. Components in the accompanying drawings are described to be larger than actual sizes for convenience of description, and the ratio of each component may be exaggerated or reduced.

When a component is described as being “on” or “adjacent to” another component, it may be directly in contact with or connected to another component, but it should be understood that there may be another component in between them. On the other hand, when a component is described as being “directly on” or “directly adjacent to” another component, it may be understood that there may not be another component in between them. Other expressions describing relationship between the components, such as “between” and “directly between”, and the like, may be interpreted in the same way.

When components are described as provided at a “same interval/height”, it may be understood that the components are provided with similar interval/height within the tolerance range.

The terms such as “first,” “second,” and so on may be used to describe a variety of elements, but the elements should not be limited by these terms. The terms are only used to differentiate one component from other components. For example, the “first” component may be named the “second” component, and vice versa, without departing from the scope of the present disclosure.

The expression such as “comprise” or “have” as used herein is intended to designate existence of a characteristic, number, step, operation, element, part or a combination thereof as specified in the description, and should not be construed as foreclosing possible existence or addition of one or more of the other characteristics, numbers, steps, operations, elements, parts or a combination thereof.

Unless terms used in the embodiments of the disclosure are defined differently, it may be interpreted as meanings commonly known to those skilled in the art. For example, the terms such as “space” or “interval” may be used to describe a distance between two objects. On the other hand, the term “interval space” as used herein is intended to describe an interval between the plurality of processed display modules 30.

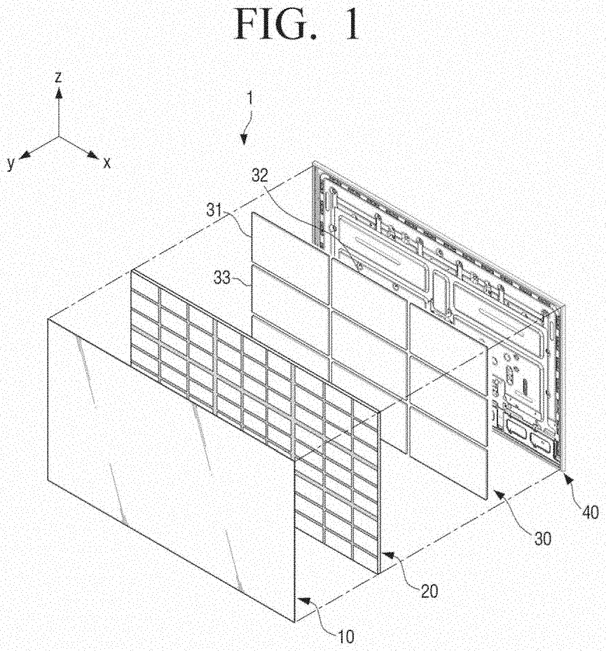

Hereinafter, a configuration of a display apparatus 1 according to an embodiment will be described in detail with reference to FIGS. 1 to 3.

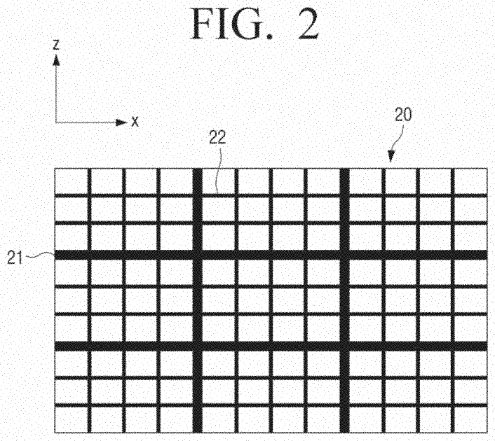

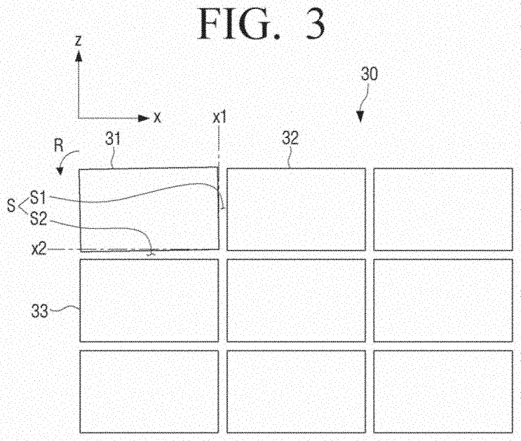

FIG. 1 is an exploded perspective view illustrating a display apparatus 1 according to an embodiment, FIG. 2 is a top view illustrating a transparent cover 20 according to an embodiment, and FIG. 3 is a top view illustrating a plurality of display modules 30 according to an embodiment.

FIG. 1 is an exploded perspective view illustrating the display apparatus 1 according to an embodiment.

A display apparatus 1 described below is a device capable of processing an image signal received from the outside and visually displaying the processed image, and may be implemented in various forms such as a television, a monitor, a portable multimedia device, a portable communication device, and the like, and if it is a device displaying an image visually, the form thereof is not limited.

As shown in FIG. 1, the display apparatus 1 may include a protective plate 10, a transparent cover 20, a plurality of processed display modules 30, and a housing 40.

The display module according to an embodiment of the disclosure may be applied to an electronic product or an electronic device that requires a wearable device, a portable device, a handheld device, or various displays, in a single unit. The display module can also be applied to a display device such as a monitor for a personal computer, a TV and digital signage, an electronic display through a plurality of assembly arrangements.

Herein, processing may include various mechanical and chemical processes such as cutting, polishing, etching, or the like.

In addition, a processed display module 30 may refer to a display module that has been processed. A protection plate 10 may be disposed on a front surface (Y-axis direction) of the display apparatus 1 and configured to protect a transparent cover 20 and the plurality of display modules 30 disposed behind the protection plate 10 from the outside.

The protective plate 10 may be made of a thin glass material and may be made of various materials as necessary.

The transparent cover 20 is a plate on which the plurality of processed display modules 30 may be disposed, and is disposed in front of the plurality of processed display modules 30. In other words, the transparent cover 20 may be disposed to face a plurality of micro LEDs 50 on top of the plurality of display modules 30. The transparent cover 20 may be formed of a flat plate, or may be formed of various shapes and sizes to fit various shapes and sizes of the plurality of display modules 30.

Accordingly, the transparent cover 20 may support the plurality of processed display modules 30 in order that the plurality of processed display modules 30 are arranged in parallel on the same plate, and the transparent cover 20 may implement the same height between the plurality of processed display modules 30 to implement uniform luminance of a display screen.

In addition, as illustrated in FIG. 3, the transparent cover 20 may be disposed with the plurality of processed display modules 30 with a space S formed in-between. The space formed between the plurality of micro LEDs 50 to be disposed in each of the plurality of processed display modules 30 may be the same.

In other words, a width of an interval space S may be an interval between the plurality of processed display modules 30.

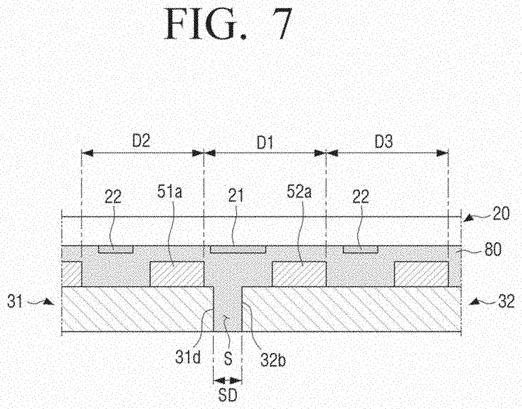

In addition, an adhesive layer 80 (refer to FIG. 7) is formed on one surface of the transparent cover 20. Accordingly, the plurality of processed display modules 30 may adhere to one surface of the transparent cover 20 to be fixed to the transparent cover 20.

In addition, the transparent cover 20 is made of a transparent material, light generated by the plurality of processed display module 30 may be transmitted through the transparent cover 20. For example, the transparent cover 20 may be made of glass.

Referring to FIG. 2, a covering 21 covering the interval space S may be formed on one surface of the transparent cover 20. The covering 21 may be made of a material that absorbs light, and may be formed on one surface of the transparent cover 20. For example, the covering 21 may be formed in a lattice form on one surface of the transparent cover 20.

The covering 21 may cover the interval space S formed between the plurality of processed display modules 30. Accordingly, when external light is introduced from the front surface (Y-axis direction) of the display apparatus 1, the external light may be absorbed such that a user may not recognize the interval space S between the plurality of processed display modules 30. Thus, a seamless display apparatus 1 may be implemented.

The covering 21 may be composed of a black matrix photosensitive resin composition for a liquid crystal display containing a binder resin, a photopolymerization initiator, a black pigment and a solvent, or a resin composition containing a black pigment for shielding.

The plurality of display modules 30 may implement light to display an image in front (Y-axis direction) according to an image signal input from the outside.

In addition, the plurality of display modules 30 may be arranged in accordance with a size of a display to be implemented by each display module 30 manufactured in a module form to form a display screen.

For example, when the first display module 31 and the second display module 32 are arranged side by side in a horizontal direction (X-axis direction), the display screen may be longer in the horizontal direction (X-axis direction) than a vertical direction (Z-axis direction).

In addition, when the first display module 31 and the third display module 33 are arranged side by side in the vertical direction (Z-axis direction), the display screen may be longer in the vertical direction (Z-axis direction) than the horizontal direction (X-axis direction).

Accordingly, display screens of various sizes and shapes may be implemented according to the number and shape of arranging the plurality of display modules 30.

After the plurality of display modules 30 have been collectively processed, the plurality of display modules 30 may be arranged with a space S formed in-between as illustrated in FIG. 3.

For example, on the basis of a first processed display module 31, a second processed display module 32 may be arranged in parallel with the first processed display module 31 with a first interval space S1 provided between the first processed display module 31 and the second processed display module 32.

In addition, on the basis of the first processed display module 31, a third processed display module 33 may be arranged in parallel with the first processed display module 31 with a second interval space S2 provided between the first processed display module 31 and the third processed display module 33.

The interval space S including the first interval space S1 and the second interval space S2 may be equally spaced between the plurality of micro LEDs 50 of each of the plurality of processed display modules 30, such that a width of the interval space S of each of the plurality of processed display modules 30 may be varied.

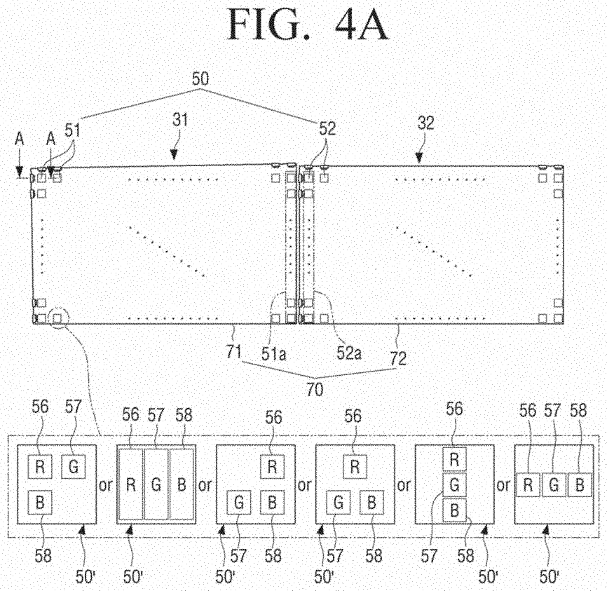

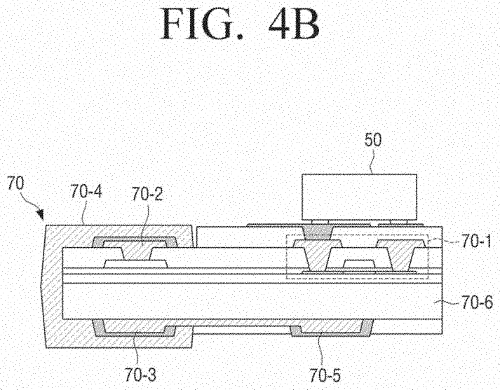

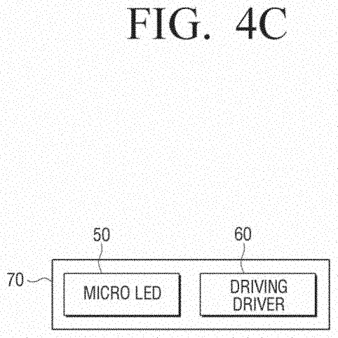

As illustrated in FIG. 4A, the plurality of micro LEDs 50 may include red micro LED 56, a green micro LED 57, and a blue micro LED 58 as one-pixel unit. In addition, the micro LED 50 may be a pixel 50′.

For example, a width of the first interval space S1 and a width of the second interval space S2 may be different.

In addition, some of the plurality of processed display modules 30 may be rotated and disposed in a predetermined direction to equalize space between all the plurality of micro LEDs 50 included in the plurality of processed display modules 30.

For example, as illustrated in FIG. 3, the first processed display module 31 may be partially rotated and arranged in an R direction.

Accordingly, a vertical side surface of the first processed display module 31 may not coincide with an extension line X1 of the vertical side surface of the third processed display module 33 disposed in a vertical direction of the first processed display module 31.

Similarly, a horizontal side surface of the first processed display module 31 may not coincide with an extension line X2 of a horizontal side surface of the second processed display module 32 disposed in the horizontal direction of the first processed display module 31.

Thus, spaces between the first plurality of micro LEDs 51 disposed on the first processed display module 31 and the second plurality of micro LEDs 52 disposed on the second processed display module 32 may be the same. Accordingly, a display screen of the display apparatus 1 may implement uniform luminance.

Although the first processed display module 31 may be partially rotated and arranged, embodiments are not limited thereto, and some of the plurality of processed display modules 30 may be rotated and arranged in one direction to maintain the same space between the plurality of micro LEDs 50.

A detailed structure of the plurality of processed display modules 30 will be described in detail with reference to FIG. 4A.

A housing 40 may form an exterior of the display apparatus 1, and be disposed behind the transparent cover 20, and stably fix the plurality of processed display modules 30 and the transparent cover 20.

In addition, the housing 40 may stably fix an edge region of a protective plate 10.

Accordingly, the housing 40 may prevent various components included in the display apparatus 1 from being exposed to the outside, and may protect various components included in the display apparatus 1 from external shock.

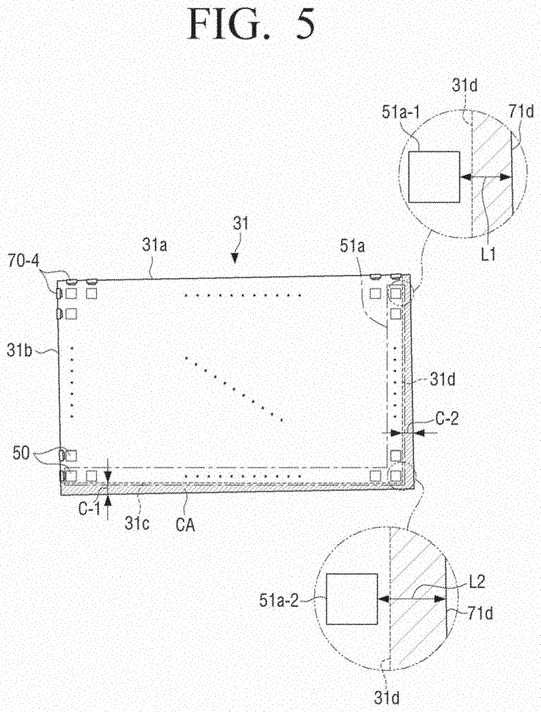

Hereinafter, a specific structure of the plurality of processed display apparatuses 1 will be described with reference to FIGS. 4A to 5.

FIG. 4A is a top view illustrating a first and second processed display modules 31 and 32 according an embodiment, FIG. 4B is a cross section view taken along line A-A of FIG. 4, FIG. 4C is a block diagram illustrating an operation of a display module according to an embodiment, and FIG. 5 is a top view illustrating a processed area CA of a first processed display module 31 according to an embodiment.

Although it is described based on the first and second processed display modules 31 and 32 of the plurality of processed display modules 30, a structure of the first and second processed display modules 31 and 32 may be the same as a structure of the processed display module 30, respectively.

Surface areas of at least two display modules of the plurality of display modules 30 may be different from each other. To be specific, surface areas of the plurality of processed display modules 30 that have been processed may be different from each other.

The surface area may refer to an area of an upper surface of one display module of the display module 30.

For example, the surface area of the processed first display module 31 and the processed second display module 32 illustrated in FIG. 4A may be different from each other. However, embodiments are not limited thereto, and surface areas of some of the processed plurality of display modules among the plurality of processed display modules may be the same.

The plurality of processed display modules 30 may include a thin film transistor substrate 70 and a plurality of micro LEDs 50 disposed on the thin film transistor substrate 70, respectively.

For example, the first processed display module 31 may include a first thin film transistor substrate 71 and a first plurality of micro LEDs 51 disposed on the first thin film transistor substrate 71.

Similarly, the second processed display module 32 may include a second thin film transistor substrate 72 and a second plurality of micro LEDs 52 disposed on the second thin film transistor substrate 72.

The thin film transistor substrate 70 may have a quadrangular shape and may stably fix the plurality of micro LEDs 50 disposed on one flat surface.

For example, the thin film transistor substrate 70 may be coupled to an electrode layer (or TFT layer) including a plurality of thin film transistors on a glass substrate.

Accordingly, a driving driver 60 (refer to FIG. 4C) for driving the thin film transistor substrate 70 may be disposed on the thin film transistor substrate 70 formed of a glass substrate 70-6 and an electrode layer to be operated. In other words, a chip-shaped driving driver 60 may be implemented in the form of a chip on glass (COG) on the thin film transistor substrate 70.

Accordingly, the driving driver 60 for driving the thin film transistor substrate 70 may be disposed and operated on the thin film transistor substrate 70 formed of a circuit board. In other words, the chip-shaped driving driver 60 may be implemented in the form of a chip on board (COB) on the thin film transistor substrate 70. For example, the driving driver 60 may be disposed behind the glass substrate 70-6. In this case, the thin film transistor substrate 70 may be made of a transparent material having a predetermined light penetrability. For example, the thin film transistor substrate 70 may include the glass substrate 70-6.

As shown in FIG. 4B, the thin film transistor substrate 70 may include a plurality of thin film transistors 70-1 for controlling and driving the plurality of micro LEDs 50 disposed on one surface thereof.

The thin film transistor 70-1 may be formed inside the thin film transistor substrate 70 and electrically connected to one micro LED 50 disposed on an upper surface of the thin film transistor substrate 70. In addition, the plurality of thin film transistors 70-1 may be disposed on an upper surface of the glass substrate 70-6.

Accordingly, the thin film transistor 70-1 may selectively drive the micro LED 50 by controlling a current flowing in the micro LED 50. In other words, the thin film transistor substrate 70 may serve as a switch for controlling a pixel, which is a basic unit of a display.

In addition, the thin film transistor substrate 70 may include a first connection pad 70-2 electrically connected to the thin film transistor 70-1 on an edge of one surface of the thin film transistor substrate 70, a second connection pad 70-3 formed on an edge of the other surface of the thin film transistor substrate 70, a side wiring 70-4 which electrically connects the first connection pad 70-2 and the second connection pad 70-3, and a driving pad 70-5 electrically connected to the second connection pad 70-3 and electrically connected to a driving driver 60 disposed on the other surface of the thin film transistor substrate 70.

Accordingly, an electrical signal for driving the plurality of micro LEDs 50 in the driving driver 60 may be transmitted to a driving pad 70-5, a second connection pad 70-4, a side wiring 70-4, the first connection pad 70-2, and the thin film transistors 70-1, and drive the plurality of micro LEDs 50, respectively.

In addition, the driving driver 60 for driving the plurality of micro LEDs 50 disposed on one thin film transistor substrate 70 may be disposed behind the thin film transistor substrate 70, and connected to the side wiring 70-4, such that the edge areas of the plurality of processed display modules 30 may be reduced or minimized and the plurality of processed display modules 30 may be disposed adjacent to each other.

Accordingly, a bezelless and seamless display apparatus 1 may be realized by minimizing space between the plurality of processed display modules 30.

In addition, the processed display module 30 according to the disclosure may be applied to a structure of a through glass via (TGV). For example, the plurality of micro LEDs 50, a via hole for connecting the driving driver 60 disposed behind the thin film transistor 70-1 and the first thin film transistor substrate 71, and a conductive material filled in the via hole may be formed on the first thin film transistor substrate 71.

In other words, processed display modules 31 and 32 may be arranged, respectively, through the structure of the through glass via (TGV) in a state in which the plurality of micro LEDs 50 and the thin film transistor 70-1, and the driving driver 60 are electrically connected.

Accordingly, the bezelless and seamless display apparatus 1 may be realized while minimizing the space between the plurality of processed display modules 30 including the TGV structure.

The micro LED 50 is made of an inorganic light emitting material having a size of 100 μm or less in width, length, and height, and is disposed on the thin film transistor substrate 70 to irradiate light by itself

The micro LED 50 may be composed of one pixel 50′, and a red micro LED 55 emitting red light, a green micro LED 56 emitting green light, and a blue micro LED 57 emitting blue light, which are sub-pixels, may be arranged in one pixel.

The sub pixels 55, 56, and 57 may be arranged in a matrix form, or may be sequentially arranged in one pixel 50′. However, the arrangement of the subpixels 55, 56, and 57 is an example, and the subpixels 55, 56, and 57 may be arranged in various forms in one pixel 50′, respectively.

In other words, the micro LED 50 may include the red micro LED 56, the green micro LED 57, and the blue micro LED 58, and the red micro LED 56, the green micro LED 57, and the blue micro LED 58 may be composed in one pixel 50. The micro LED 50 has a relatively fast response speed, low power, and high luminance, and thus is being used as a light emitting device of a next generation display. Specifically, the micro LED 50 has a higher efficiency in converting electricity into photons compared to conventional liquid crystal displays (LCDs) or organic LEDs (OLEDs).

The micro LED 50 may have a higher brightness per watt than that of conventional LCD or OLED displays. This allows the micro LED 50 to achieve the same brightness with about half energy of the conventional LEDs or OLEDs.

In addition, the micro LED 50 may realize high resolution, excellent color, contrast and brightness, may accurately express a wide range of colors, and may realize a clear screen even in the outdoors under the bright sunlight. In addition, the micro LED 50 may be strong in burn-in phenomenon and generates less heat, thereby ensuring a longer life without deformation.

In addition, the micro LED 50 may be a flip chip.

The plurality of micro LEDs 50 may be disposed on the processed display module 30 at equal space. In other words, the plurality of micro LEDs 50 disposed on one processed display module 30 may be arranged at regular intervals in a matrix form.

For example, a first plurality of micro LEDs 51 disposed on the first processed display module 31 may be arranged at equal intervals, and may be arranged in a plurality of columns and rows that are parallel to each other

Similarly, the second plurality of micro LEDs 52 disposed on the second processed display module 32 may be arranged at equal intervals, and may be arranged in a plurality of columns and rows that are parallel to each other.

In addition, as shown in FIG. 5, the shortest distance from a first edge micro LED MA disposed on one side portion of the first plurality of micro LEDs 51 disposed on the first display module to a side surface of the first display module 31 adjacent to the first edge micro LED 51 may be different.

The processed display module may be a display module in which a side is processed through a processing process, and the display module may be a display module in a state before the processing process.

For example, a distance L1 from a top-first edge micro LED 51A-1 disposed at the upper end of the first display module among the first plurality of edge micro LEDs 51A to a third side surface of the first display module before being processed 71D may be smaller than a distance L2 from a bottom-first edge micro LED 51A-2 disposed at the lower end of the first display module among the first plurality of edge micro LEDs 51A.

In other words, when the first plurality of micro LEDs 51 are arranged on the first display module 31 non-parallel to the horizontal side surface and the vertical side surface of the first display module 31, a distance between the first edge micro LEDs 51A and one side of the first display module 31 may be different.

When the first plurality of micro LEDs 51 are arranged on the first display module 31 non-parallel to the horizontal side surface and the vertical side surface of the first display module 31, when the first display module 31 and the second display module 32 are not processed, and space between the first plurality of micro LEDs 51 and the second plurality of micro LEDs 52 is regularly arranged to be constant, the edges of side surfaces of the first display module 31 and the second display module 32 are physically in contact with each other, such that space between the first plurality of micro LEDs 51 and the second plurality of micro LEDs 52 may not be regularly arranged.

However, even when the first plurality of micro LEDs 51 are arranged on the first display module 31 non-parallel to the horizontal side surface and the vertical side surface of the first display module 31, space between the first processed display module 31 and the second processed display module 32 may be minimized by processing the processed area CA of the first display module 31, thereby regularly arranging the interval between the first plurality of micro LEDs 51 and the second plurality of micro LEDs 52.

In other words, the first processed display module 31 and the second processed display module 32 disposed adjacent to the first processed display module 31 may be arranged in order for space between the first edge micro LED MA of the first processed display module 31 and the second edge micro LED 52A disposed on one side of the second plurality of micro LEDs 52 of the processed display module 32 to be regular.

Accordingly, it may be possible to implement uniform luminance of the display screen in the display apparatus 1 and a seamless display between the plurality of display modules by maintaining the same space between the first plurality of edge micro LEDs MA and the second plurality of edge micro LEDs 52B.

In addition, even if the plurality of micro LEDs 50 are arranged not parallel to a horizontal side surface and a vertical side surface of the display module 30, a yield of a manufacturing process may be increased by processing the side surfaces of the display module 30.

The first processed display module 31 may be a rectangular shape and have a first side surface 31A, a second side surface 31B adjacent to the first side surface 31A, a first processed surface 31C facing the first side surface 31A, and a second processed surface 31D facing the second side surface 31B and adjacent to the first processed surface 31C.

A structure of the first processed display module 31 will be described, but the structure of the first processed display module 31 is the same as that of the plurality of processed display modules 30.

Side wires 70-4 may be formed on the first side surface 31A and the second side surface 31B.

In addition, the first processing surface 31C may be processed to be parallel to a row of the first plurality of micro LEDs 50 disposed on the first processed display module 31. In addition, the second processing surface 31D may be processed to be parallel to a row of the plurality of micro LEDs 50 disposed on the first processed display module 31.

Accordingly, a distance between the first edge micro LED 51A disposed on an edge of the first processed display module 31 among the first plurality of micro LED 50 and the first and second processed surfaces 31C and 31D may be decreased.

Therefore, when the second processed display module 32 is arranged adjacent to the first processed display module 31, a distance between the first edge micro LED 51A and the second edge micro LED 52B may be regularly arranged. In other words, the first processed display 31 and the second processed display module 21 may be arranged such that the distance between the first edge micro LED MA and the second edge micro LED 52B may equal to the distance between the first plurality of micro LEDs 51 and the second plurality of micro LEDs 52.

Accordingly, it is possible to implement uniform luminance of the display screen implemented in the display apparatus 1 and to implement seamless display among the plurality of display modules.

Meanwhile, referring back to FIG. 5, the processed area CA processed in the plurality of display modules 30 may be processed to have the same first processed width C-1 and the same second processed width C-2.

For example, both the first processed display module 31 and the second processed display module 32 may be processed to have the same first machined width C-1 and the same second machined width C-2.

Accordingly, even when sizes of the plurality of display modules 30 are different due to manufacturing tolerances, edge areas of the plurality of display modules 30 may be reduced by collectively processing with the first machined width C-1 and the second machined width C-2.

Thus, a plurality of adjacent processed display modules 30 may be arranged in order that the plurality of micro LEDs 50 have a regular space due to the reduction of edge areas of the plurality of processed display modules 30.

In other words, due to manufacturing tolerances, due to a contact of the edge areas of the plurality of display modules 30, the plurality of micro LEDs 50 may not be arranged to have regular intervals, but through the processing process, the plurality of adjacent processed display modules 30 may be arranged in order that the plurality of micro LEDs 50 have a regular space, by processing a portion of the plurality of display modules 30.

Accordingly, manufacturing costs for implementing a uniform display screen can be reduced, yields can be improved, and uniformity of the luminance of the display screen can be realized.

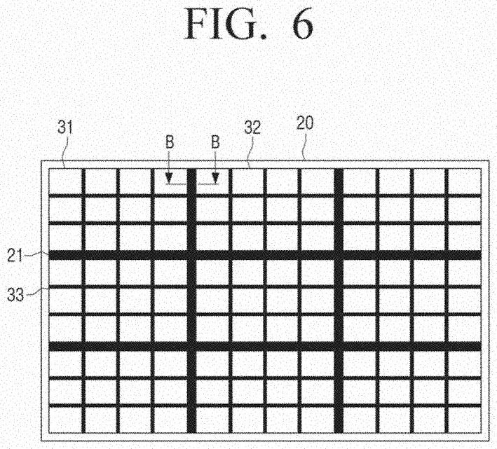

Hereinafter, a structure in which the transparent cover 20 and the plurality of processed display modules 30 are combined will be described in detail with reference to FIGS. 6 and 7.

FIG. 6 is a top view illustrating that a plurality of display modules are disposed on a transparent cover according to an embodiment, and FIG. 7 is a cross section view taken along line B-B of FIG. 6.

As shown in FIG. 6, the plurality of processed display modules 31 may be fixed behind the transparent cover 20.

For example, as illustrated in FIG. 7, the plurality of processed display modules 30 may be arranged with a space in-between, and the space S may be covered by the covering 21.

For example, the first processed display module 31 and the second processed display module 32 may be arranged with a space in-between.

The interval space distance (SD) of the interval space (S) may be adjusted such that a first distance D1 between the first edge micro LED 51A and the second edge micro LED 52A is the same as a second distance D2, which is a regular interval between the first plurality of micro LEDs 51, and a third distance D3, which is a regular interval between the second plurality of micro LEDs 52.

The first processed display module 31 and the second processed display module 32 may be disposed in order for the first interval D1 between the first edge micro LED 51A and the second edge micro LED 52A to be the same as the second interval D2, which is a regular interval between the plurality of micro LEDs 51, and the third interval D3, which is a regular interval between the plurality of micro LEDs 52.

Therefore, the second interval D2 and the third interval D3 are the same as arrangement intervals P between the plurality of micro LEDs 50.

Accordingly, it is possible to implement uniform luminance of the display screen implemented in the display apparatus 1 and to implement seamless display among the plurality of display modules.

In addition, the first processed display module 31 and the second processed display module 32 may be disposed on the transparent cover 20 so that the interval space S is covered by the covering 21 of the transparent cover 20.

Therefore, the first processed surface 31C and the second processed surface 31D of the first processed display module 31 may be covered by the covering 21.

Accordingly, when external light flows into the first processed surface 31C and the second processed surface 31D on which the side surfaces of the plurality of display modules are processed, the covering 21 may absorb the external light so as to prevent the external light from being diffusely reflected by contacting the first processed surface 31C and the second processed surface 31D.

In particular, when the thin film transistor substrate 70 of the plurality of processed display modules 30 is formed of a glass substrate, the user may recognize a seam due to diffused reflection caused by external light, but the covering 21 may implement the seamless display by absorbing external light that flows into the display apparatus 1.

In other words, the plurality of processed display modules 30 have the same interval between the plurality of micro LEDs 50, and the interval space S between the plurality of processed display modules 30 may be disposed to be covered by the covering 21.

In addition, the transparent cover 20 may include an additional covering 22 to cover space between the plurality of micro LEDs 50.

For example, when the plurality of micro LEDs 50 are arranged in a matrix form on the first thin film transistor substrate 71, a constant interval may be formed between the plurality of micro LEDs 50. In this case, the transparent cover 20 may cover the space between the plurality of micro LEDs 50 by having the additional covering 22 in addition to the covering 21.

Accordingly, the additional covering 22 may absorb external light flowing into the display apparatus 1 similar to the covering 21, thereby realizing the seamless display of the display apparatus 1.

In addition, the additional covering 22 may be made of the same material as the covering 21, and the covering 21 and the additional covering 22 may be simultaneously formed on one surface of the transparent cover 20.

In addition, a width of the additional covering 22 may be equal to or smaller than a width of the covering 21.

In addition, an adhesive layer 80 may be formed between the plurality of processed display modules 30 and the transparent cover 20 to fix the plurality of processed display modules 30 to the transparent cover 20.

In this case, the adhesive layer 80 is formed to cover side surfaces of the plurality of processed display modules 30 by filling the interval spaces S, thereby stably fixing the plurality of processed display modules 30 to the transparent cover 20.

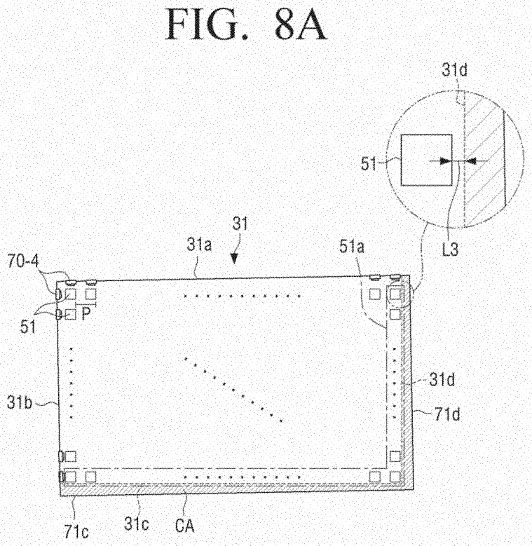

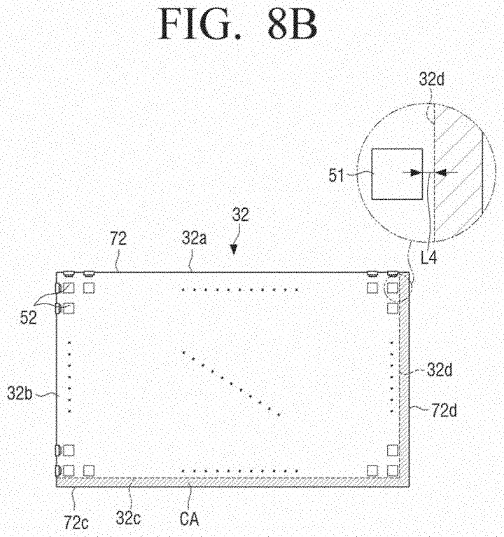

Hereinafter, a manufacturing process of the display apparatus 1 will be described in detail with reference to FIGS. 8A to 14.

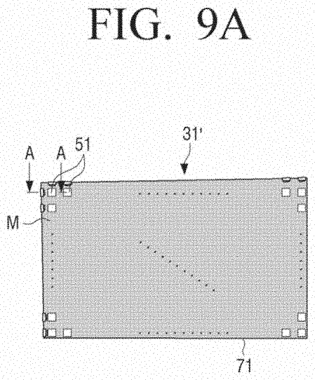

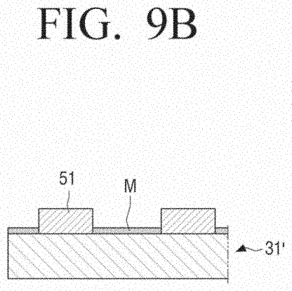

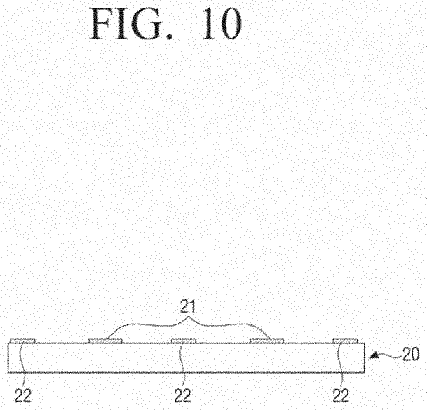

FIG. 8A is a top view illustrating a process of processing a first display module according to an embodiment, FIG. 8B is a top view illustrating a process of processing a second display module according to an embodiment, FIG. 9A is a top view illustrating a first processed display module according to another embodiment, FIG. 9B is a cross section view taken along line F-F of FIG. 9A, and FIGS. 10 to 14 are schematic diagrams illustrating a process of arranging a plurality of processed display modules.

The processed display module may be a display module in which a side is processed through a processing process, and the display module may be a display module in a state before the processing process.

First, as illustrated in FIG. 8A, the first plurality of micro LEDs 51 are mounted on a manufactured first display module 31 at regular intervals in a matrix form. For example, the plurality of micro LEDs 50 may be arranged by units of pixels on the upper surfaces of the plurality of display modules 30, respectively.

In this case, due to manufacturing tolerances, rows and columns of the first plurality of micro LEDs 51 that are not parallel to a horizontal side surface and the vertical side surface of the first display module may be provided. In addition, due to manufacturing tolerances, sizes between the plurality of processed display modules 30 may be different.

In other words, the shortest interval between a first plurality of edge micro LEDs 51A disposed on one side of the first plurality of micro LEDs 51 and the horizontal side surface 71C and the vertical side surface 71D of the first display module before processing may be different.

Next, the first display module may process a side of the first display module to make the shortest interval L3 between the first plurality of edge micro LEDs 51A and one side surface of the first processed display module smaller than intervals P between the plurality of micro LEDs 50.

Here, the arrangement intervals P between the plurality of micro LEDs 50 may refer to an interval between the first plurality of micro LEDs 51.

For example, as shown in FIG. 8A, the shortest interval L3 between the first edge micro LED 51A and the second processed surface 31D formed after processing the processed area CA of the first display module 31 may be smaller than intervals between the first plurality of micro LEDs 51.

Accordingly, when the first processed display module 31 and the second processed display module 32 are arranged side by side, the first processed display module 31 and the second processed display module 32 may be arranged on the transparent cover 20 in order for an interval between the first edge micro LED 51A and the second edge micro LED 51B of the second processed display module disposed closest to the first edge micro LED 51A to be the same.

Here, the interval between the first edge micro LED 51A and the second edge micro LED 52A may be equal to the arrangement intervals P between the plurality of micro LEDs 50.

In addition, side surfaces of the plurality of display modules 30 may be processed. For example, processing may collectively process the first side surface and the second side surface adjacent to the first side surface of the plurality of display modules 30 having a rectangular shape, respectively.

In addition, the processed side surface of the first display module 31 may process the side surface of the first display module 31 to be parallel to at least one of the rows and columns of the first plurality of micro LEDs 51 disposed on the first display module 31.

For example, as shown in FIG. 8A, the first display module 31 may be processed such that the first processed surface 31A formed after processing the processed area CA is parallel to a row of the first plurality of micro LED 51.

The first display module 31 may be processed such that the second processed surface 31D formed after processing the processed area CA is parallel to a row of the first plurality of micro LEDs 51.

Accordingly, even when the rows and columns of a first plurality of micro LEDs 51 are disposed non-parallel to the horizontal side and the vertical side of the first display module due to manufacturing tolerances, the first and second processed surfaces 31C and 31D of the first processed display module 31 may be parallel to the rows and columns of the first plurality of micro LEDs 51 through the process of processing.

Accordingly, when the first processed display module 31 and the second processed display module 32 are arranged side by side, adjacent and opposing side surfaces of each other may be arranged in parallel, thereby improving an accuracy of the arrangement process.

In addition, the plurality of display modules 30 may process two adjacent side surfaces among the plurality of side surfaces of the plurality of display modules, respectively. In addition, side wirings may be formed on the remaining two sides of the plurality of processed display modules, respectively, in addition to the two processed side surfaces.

For example, as shown in FIG. 8A, side wirings 70-4 may be formed at the first processed surface 31 C of the first processed display module 31, the first side surface 31A of the first processed display module 31 in addition to the second processed surface 32D and the second side surface 31B.

Similarly, as shown in FIG. 8B, side wirings 70-4 may be formed at the first processed surface 32C of the second processed display module 32, the first side surface 31A of the second processed display module 32 in addition to the second processed surface 32D and the second side surface 32B.

The side wiring 70-4 may be formed after the plurality of display modules 30 are processed, or may be formed before the plurality of display modules 30 are processed, as needed.

In addition, the process of processing the plurality of display modules 30 may be processed through laser cutting, or through a mechanical processing process.

Meanwhile, as shown in FIG. 8B, rows and columns of the second plurality of micro LEDs 52 disposed on the second display module 32 may be mounted to be parallel to the horizontal side and the vertical side of the second display module 32, respectively.

In other words, the rows and columns of the first plurality of micro LEDs 51 described above are not disposed parallel to the horizontal side and the vertical side of the first display module 31, while the rows and columns of the second plurality of micro LEDs 52 may be disposed to be parallel to the horizontal side and the vertical side of the second display module 32.

However, even in this case, the second display module 32 may be processed in the same manner as the first display module 31.

For example, the second display module 32 may be processed such that the side surfaces of the second display has the shortest interval between the second plurality of edge micro LEDs 52A and one side of the second processed display module 32 that is smaller than the arrangement intervals P between thee plurality of micro LEDs 50.

The arrangement intervals P between the plurality of micro LEDs 50 may refer to an interval between the second plurality of micro LEDs 52. In addition, the arrangement intervals P may refer to an interval between the first and second plurality of micro LEDs 51 and 52.

For example, as shown in FIG. 8B, the shortest interval L to the second processed surface 32D formed after processing the processed area CA of the second edge micro LED 52A and the second display module 32 may be smaller than the interval between the second plurality of micro LEDs 52.

In addition, the processed side surface of the second display module 32 may process the second display module 32 to be parallel to at least one of the rows and columns of the second plurality of micro LEDs 52 disposed on the second display module 32.

For example, as shown in FIG. 8B, the second display module 32 may be processed such that a first processed surface 32C formed after the processed area CA is processed to be parallel to the row of the second plurality of micro LEDs 52.

Similarly, the second display module 32 may be processed such that the second processed surface 32D formed after the processed area CA is processed to be parallel to the row of the second plurality of micro LEDs 52.

Accordingly, as the plurality of display modules 30 are collectively processed, the shortest interval between the plurality of edge micro LEDs disposed on the edges of the plurality of display modules 30 and the plurality of processed display modules 30 may be reduced.

Therefore, when the plurality of display modules 30 are disposed on the transparent cover 20, space between the plurality of micro LEDs 50 disposed on each of the plurality of display modules 30 may be the same.

In other words, even when some of the plurality of display modules are disposed by rotating or moving in an X and Z axes, it may prevent or reduce the edges of the adjacent plurality of display modules 30 from being contacted in order to dispose intervals between the plurality of micro LEDs 50 to be the same.

In addition, as shown in 9A and 9B, light absorbing layer M may be formed on a first thin film transistor substrate 71 in a processed first display module 31′.

The light absorbing layer M may be composed of a black matrix photosensitive resin composition for a liquid crystal display containing a black pigment and a solvent or a resin composition containing a black pigment for shielding.

Specifically, the light absorbing layer M may be applied to a region where the plurality of micro LEDs 51 are not mounted on the first thin film transistor substrate 71.

For example, the light absorbing layer M may be formed after the plurality of micro LEDs 51 are mounted on the first thin film transistor substrate 71 or may be formed the first thin film transistor substrate 71 before the plurality of micro LEDs are mounted on the first thin film transistor substrate 71.

Accordingly, the light absorbing layer M may absorb external light flowing from the outside of the display apparatus 1 to implement a seamless display of the display apparatus 1.

In addition, the light absorbing layer M may be composed of the same material as the covering 21 and the additional covering 22. For example, a color of the light absorbing layer M may be the same as a color of the covering 21 and the additional covering 22.

Accordingly, the light absorbing layer M may absorb, similar to the covering 21, external light flowing into the display apparatus 1 and some of light of the plurality of micro LEDs 50 that are not necessary in implementing the display screen, thereby enhancing the effect of implementing the seamless display of the display apparatus 1.

In addition, the light absorbing layer M may cover a processed side surface of the first thin film transistor substrate 71. Accordingly, when the first thin film transistor substrate 71 is formed of glass, the light absorbing layer M may absorb light introduced from the outside to prevent or reduce diffuse reflection of external light from the processed side surface.

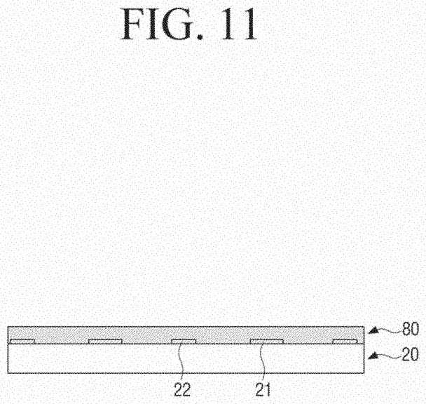

Next, as illustrated in FIGS. 10 and 11, an adhesive layer 80 may be formed on one surface of the transparent cover 20 on which the covering 21 is formed.

The adhesive layer 80 is to fix the plurality of processed display modules 30 to the transparent cover 20, and may be composed of a transparent material having adhesiveness. Accordingly, when light is irradiated from the plurality of processed display modules 30, the adhesive layer 80 may be transmitted.

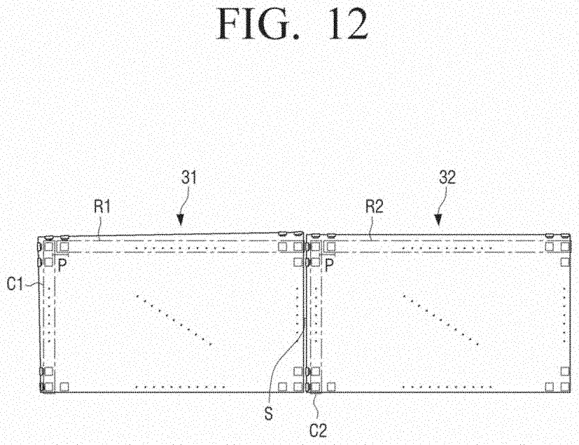

Then, as shown in FIG. 12, the plurality of processed display modules 30 may be disposed on the transparent cover 20 on which the adhesive layers 80 is formed in order for the plurality of micro LEDs 50 of the plurality of processed display modules 30 have the same LED space, respectively.

For example, an interval P between the first plurality of micro LEDs 51 of the first processed display module 31 and the second plurality of micro LEDs 52 of the second processed display module 32 may be equal to the arrangement intervals P between the first plurality of micro LEDs 51 and the arrangement intervals P between the second plurality of micro LEDs 52.

Specifically, the first processed display module 31 and the second processed display module 32 may be disposed on the transparent cover 20 in order to make a regular space between the first plurality of edge micro LEDs MA disposed on one side of the first processed display module 31 among the plurality of processed display modules 30 and the second plurality of edge micro LEDs 52A disposed on one side of the second processed display module 32 disposed adjacent to one side of the processed display module 31.

Similarly, the plurality of processed display modules 30 may arrange the plurality of processed display modules 30 such that the pixels 50′ have the same space.

Therefore, since the space between the plurality of micro LEDs 50 including the first and second plurality of micro LEDs 51 and 52 for implementing the display screen is the same, it is possible to implement uniform luminance of the display screen and seamless display between the plurality of processed display modules 30.

In addition, the first processed display module 31 and the second processed display module 32 may be arranged with the interval space S between the first processed display module 31 and the second processed display module 32.

The interval space S is a space formed between side surfaces of the first processed display module 31 and the second processed display module 32 facing each other, and may be adjusted in order for a first interval D1 between the first edge micro LED MA and the second edge micro LED 52A to be the same as a second interval D2 which is a constant interval between the first plurality of micro LEDs 51 and a third interval D3 which is a constant interval between the second plurality of micro LEDs 52 by adjusting an interval space distance SD of the interval space S.

In addition, the first processed display module 31 and the second processed display module 32 may be disposed so that the interval space S is covered by the covering 21 of the transparent cover 20.

Accordingly, even when external light is introduced into the display apparatus 1, the user may be prevented from recognizing the seam due to the interval space between the first processed display module 31 and the second processed display modules 32 as the covering 21 absorbs external light.

In addition, when the first processed display module 31 and the second processed display module 32 are arranged sequentially in a horizontal direction, the first processed display module 31 and the second processed display module 32 may be disposed on the transparent cover 20 in order for the row R1 of the first processed display module 31 and the row R2 of the second processed display module 32 to be disposed on the same line.

Meanwhile, when the first processed display module 31 and the second processed display module 32 are sequentially arranged in a vertical direction, the first processed display module 31 and the second processed display module 32 may be disposed on the transparent cover 20 in order the column Cl of the first processed display module 31 and the column C2 of the second processed display module 32 to be disposed on the same line.

Accordingly, since the arrangement intervals P between the plurality of micro LEDs 50 are all the same, uniform luminance of the display screen may be realized.

The first processed display module 31 and the second processed display module 32 are not limited to those described in the horizontal direction or the vertical direction, and are not limited to the horizontal direction of the first processed display module 31, and. The second processed display module 32 may be arranged in the horizontal direction of the first processed display module 31, and the third processed display module 33 may be arranged in the vertical direction of the first processed display module 31. In this case, the columns and the rows may be arranged on the same line, respectively.

In addition, when arranging the plurality of processed display modules 30, sizes of the plurality of processed display modules 30 may be measured, and based on the measured sizes, the plurality of processed display module 31 disposed on the transparent cover 20 may be selectively disposed.

For example, when considering the plurality of processed display modules 30 have the same space between the plurality of micro LEDs 50, and the interval space S between the plurality of processed display modules 30 should be disposed to be covered by the covering 21, it is possible to determine the arrangement of the plurality of display modules based on the measured size data of the processed display module.

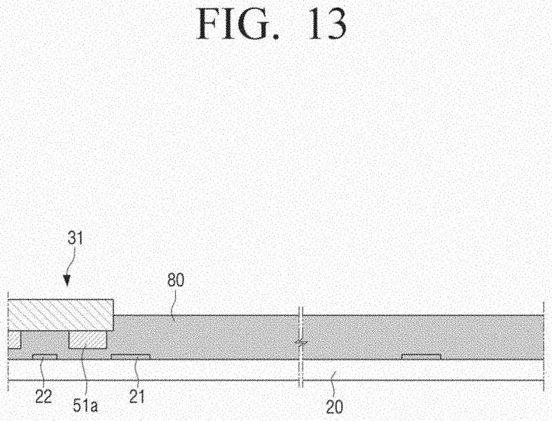

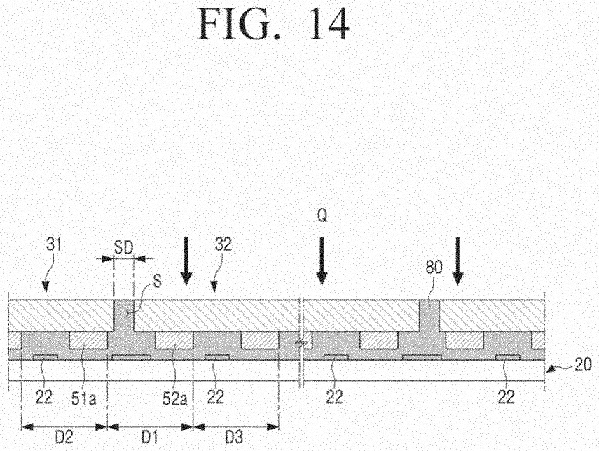

In addition, as shown in FIGS. 13 and 14, the first processed display module 31 and the second processed display module 32 may be attached sequentially to one surface of the transparent cover 20 on which the adhesive layer 80 is formed.

Next, as shown in FIG. 14, the plurality of processed display modules 30 may be thermally compressed. Accordingly, as the adhesive layer 80 is solidified, the plurality of processed display modules 30 may be stably fixed to one surface of the transparent cover 20.

In addition, the plurality of processed display modules 30 may be thermally compressed in a Q direction to have the same height with respect to the transparent cover 20. For example, the plurality of processed display modules 30 with respect to the transparent cover 20 may have the same height by pressing the plurality of processed display modules 30 with a flat plate and transferring heat at the same time.

Accordingly, the luminance for implementing the display screen may be maintained uniformly through the structure in which the plurality of processed display modules 30 are arranged to have parallel and uniform heights.

The various example embodiments aforementioned were explained separately, but each of the example embodiments may not necessarily be realized separately, and the configuration and operation of each of the example embodiments may be realized in combinations with at least one other example embodiment.

The foregoing exemplary embodiments are merely exemplary and are not to be construed as limiting the present disclosure. The present disclosure can be readily applied to other types of apparatuses. Also, the description of exemplary embodiments is intended to be illustrative, and not to limit the scope of the claims and their equivalents, and many alternatives, modifications, and variations will be apparent to those skilled in the art.

What is claimed is:

1. A method of manufacturing display apparatus comprising:
processing side surfaces of a plurality of display modules, each of the plurality of display modules comprising a plurality of micro light emitting diodes (LEDs) provided in pixels on an upper surface of each of the plurality of display modules; and
providing the plurality of processed display modules such that the pixels of the plurality of processed display modules are provided at a same interval, respectively,
wherein each of the plurality of display modules has a rectangular shape, and
wherein the processing the side surfaces of the plurality of display modules comprises processing a first side surface of each of the plurality of display modules and a second side surface of each of the plurality of display modules that are adjacent to the first side surface.

2. The method as claimed in claim 1, wherein the processing the side surfaces of the plurality of display modules comprises processing at least two display modules of the plurarlity of display modules such that at least two or more display modules of the plurality of display modules have different surface areas.

3. The method as claimed in claim 1 further comprising forming an adhesive layer on one surface of a transparent cover,
wherein the providing the plurality of processed display modules comprises providing the first processed display module and the sescond processed display module on the transparent cover, respectively, such that intervals between a plurality of first edge micro LEDs provided on one side surface of the first processed display module among the plurality of processed display module are equal to intervals between a plurality of second edge micro LEDs provided on one side surface of the second processed display module that are provided adjacent to one side surface of the first processed display module, and
providing the plurality of processed display modules on a transparent cover formed with the adhesive layer.

4. The method as claimed in claim 3, wherein the processing comprises processing a side surface of the first display module such that a distance between the plurality of first edge micro LEDs and one side surface of the first display module is smaller than a distance between each of the plurality of micro LEDs.

5. The method as claimed in claim 1, wherein the processing the side surfaces of the plurality of display modules further comprises processing the side surface of the first display module such that the processed side surface of the first display module is parallel to at least one of rows and columns of the plurality of first micro LEDs provided on the first display module.

6. The method as claimed in claim 3, wherein the providing the plurality of processed display modules further comprises providing the first processed display module and the sescond processed display module on the transparent cover such that the first processed display module and the second processed display module are provided with an interval space between the first processed display module and the second processed display module.

7. The method as claimed in claim 6, wherein the transparent cover comprises a covering formed in the form of a lattice and configured to absorb external light, and
wherein the providing the plurality of processed display modules further comprises providing the first processed display module and the second processed display module on the transparent cover such that the interval space is covered by the covering.

8. The method as claimed in claim 3, wherein the providing the plurality of processed display modules further comprises providing the first processed display module and the second processed display module on the transparent cover such that rows and columns of the plurality of the first micro LEDs provided on the first processed display module are parallel to rows and columns of the plurality of second micro LEDs provided on the second processed display module, respectively.

9. The method as claimed in claim 8, wherein the providing the plurality of processed display modules further comprises providing the first processed display module and the second processed display module on the transparent cover such that the rows of the first processed display module and the rows of the second processed display module are collinear.

10. The method as claimed in claim 8, wherein the providing the plurality of processed display modules further comprises providing the first processed display module and the second processed display module on the transparent cover such that the columns of the first processed display module and the columns of the second processed display module are collinear.

11. The method as claimed in claim 1 further comprising forming side wirings on two sides of the plurality of processed display modules, respectively, other than the first side surface and the second side surface of the plurality of processed display modules.

12. The method as claimed in claim 6 further comprising compressing thermally the plurality of processed display modules, and filling the adhesive layer in the interval space.

13. A display apparatus comprising:
a plurality of display modules in which a plurality of a micro light emitting diodes (LEDs) are provided in pixels, respectively; and
a transparent cover provided to face the plurality of micro LEDs on an upper part of the plurality of display modules,
wherein each of the plurality of display modules comprises a thin film transistor substrate electrically connected to the plurality of micro LEDs, each of the plurality of display modules comprising a glass substrate and a plurality of thin film transistors provided on an upper surface of the glass substrate; and
a driving driver provided on a surface of the glass substrate and configured to drive the plurality of micro LEDs, and
wherein at least two or more display modules of the plurality of display modules have different surface areas.

14. The display apparatus as claimed in claim 13, wherein a shortest distance between a first edge micro LED provided on one side surface of a plurality of first micro LEDs provided on a first processed display module among the plurality of processed display modules and a side surface of the first processed display module adjacent to the first edge micro LED is different, and
wherein the first processed display module and the second processed display module provided adjacent to the first processed display module are provided such that an interval between the first edge micro LED of the first processed display module and the second edge micro LED provided one side surface of a plurality of second micro LEDs of the second processed display module is regular.

15. The display apparatus as claimed in claim 14, wherein the plurality of processed display modules have a rectangular shape, respectively,
wherein the first processed display module comprises:
a first side surface;
a second side surface adjacent to the first side surface;
a first processed surface facing the first side surface; and
a second processed surface facing the second side surface and adjacent to the first processed surface, and
wherein the first processed surface and the second processed surface are covered by a covering.

16. The display apparatus as claimed in claim 15, wherein the first processed surface is parallel to rows of the plurality of first micro LEDs.

17. The display apparatus as claimed in claim 15, wherein the first processed surface is parallel to columns of the plurality of first micro LEDs.

18. The display apparatus as claimed in claim 13, wherein the plurality of micro LEDs comprises:
a red micro LED configured to emit red light;
a green micro LED configured to emit green light; and
a blue micro LED configured to emit blue light, and
wherein the red micro LED, the green micro LED and the blue micro LED are included in one pixel.

19. The display apparatus as claimed in claim 13, further comprising an adhesive layer provided between the plurality of display modules and the transparent cover, and configured to fix the plurality of display modules on the transparent cover.

20. The display apparatus as claimed in claim 13, wherein the transparent cover further comprises an additional covering that covers space between the plurality of micro LEDs.
